(19) United States
(12) Patent Application Publication
(10) Pub. No.: US 2013/0199606 A1
(43) Pub. Date: Aug. 8, 2013

(54) METHODS OF MANUFACTURING BACK SURFACE FIELD AND METALLIZED CONTACTS ON A SOLAR CELL DEVICE

(71) Applicants: Shuran Sheng, Cupertino, CA (US); Lin Zhang, San Jose, CA (US); David Tanner, San Jose, CA (US); Xuesong Lu, Santa Clara, CA (US)

(72) Inventors: Shuran Sheng, Cupertino, CA (US); Lin Zhang, San Jose, CA (US); David Tanner, San Jose, CA (US); Xuesong Lu, Santa Clara, CA (US)

(73) Assignee: APPLIED MATERIALS, INC., Santa Clara, CA (US)

(21) Appl. No.: 13/366,817

(22) Filed: Feb. 6, 2012

(51) Int. Cl. H01L 31/0224; H01L 31/18

(52) U.S. Cl. 136/256; 438/98; 257/E31.124

(57) ABSTRACT

Embodiments of the present invention are directed to a process for making solar cells. In one embodiment, a method of manufacturing a solar cell device, includes providing a substrate having a first surface and a second surface, selectively disposing a first metal paste in a first pattern on the first surface of the substrate, forming a first dielectric layer over the first metal paste on the first surface of the substrate, forming a second metal paste in a second pattern over the first dielectric layer align with the first metal paste, and simultaneously heating the first and the second metal pastes disposed on the first surface of the substrate to form a first group of contacts on the first surface of the substrate, wherein at least a portion of the second metal paste forms the first group of contacts that each extend through the first dielectric layer to connect with the first metal paste to the first surface of the substrate.

### BACKGROUND OF THE INVENTION

1. Field of the Invention

Embodiments of the present invention generally relate to a process for forming crystalline solar cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

There are various approaches for fabricating the active regions and the current carrying metal lines, or conductors, of the solar cells. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. A good passivation layer can provide a desired film property that reduces recombination of the electrons or holes in the solar cells and redirects electrons and charges back into the solar cells to generate photocurrent. When electrons and holes recombine, the incident solar energy is re-emitted as heat or light, thereby lowering the conversion efficiency of the solar cells.

A passivation layer disposed on a back surface of solar cell devices may be a dielectric layer providing good interface properties that reduce the recombination of the electrons and holes, drives and/or diffuses electrons and charge carriers back to junction regions formed in the substrate and minimize light absorption. In conventional practice, the passivation layer may be etched, drilled and/or patterned to form openings (e.g., back contact through-holes) that allow portions of the blanket back contact metal layer to extend through the passivation layer to form an electrical contact with the active regions of the device. The conventional passivation layer processing sequences, which typically include laser ablation of the passivation layer steps, post laser process cleaning steps, and blanket rear surface metal deposition steps, are costly and require a large number of processing steps and may create undesirable contamination that can inadvertently damage the solar cell substrate. Furthermore, conventional laser ablation processes often result in void and undesired defects on the passivation layer after the openings are formed in the passivation layer. For example, due to the high energy of the laser power used to drill/pattern the passivation layer, film layers adjacent to the openings formed in the passivation layer often suffer from film crack, pits, void, or seams. When a metal layer is later filled into the openings formed in the passivation layer, these defects may later cause the metal element to leak out to the passivation layer adjacent to the openings, thereby adversely resulting in short circuit and device failure.

Recently, some conventional local rear contact formation processes have gained attention for their high local doping efficiency and less complex manufacturing process steps. However, these conventional local rear contact formation processes have undesirable features, such as the creation of voids between the metal layers and the solar cell substrate at the formed contacts due to different diffusion rate or thermal expansion rate of the metal layers and the silicon elements from the adjacent film layers at the substrate interface, which generally leads to device failure or low solar cell efficiency.

Therefore, there exists a need for an improved apparatus and method of manufacturing solar cell devices that each have a desirable device performance as well as a low manufacture cost.

### SUMMARY OF THE INVENTION

Embodiments of the present invention are directed to a process for making solar cells. In one embodiment, a method of manufacturing a solar cell device includes selectively disposing a first metal paste in a first pattern on a first surface of a substrate, depositing a first dielectric layer over the first metal paste and the first surface of the substrate, depositing a second metal paste in a second pattern on the first dielectric layer and over the first metal paste, and simultaneously heating the substrate to form a first group of contacts on the first surface of the substrate, wherein each of the first group of contacts comprise at least a portion of the first and second metal pastes, and extend through the first dielectric layer.

In another embodiment, a method of manufacturing a solar cell device includes selectively disposing a first metal paste in a first pattern on a first surface of a substrate, depositing a first dielectric layer over the first metal paste on the first surface of the substrate, depositing a second metal paste in a second pattern over the first dielectric layer align with the first metal paste, forming a third metal paste in a third pattern on a second dielectric layer disposed on a second surface of the substrate, and simultaneously heating the first, the second, and the third metal pastes to form a first group of contacts on the first surface of the substrate and a second group of the contacts on the second surface of the substrate, wherein at least a portion of the first and second metal pastes forms the first group of contacts that each extend through the first dielectric layer.

In yet another embodiment, a solar cell device includes a first group of conductive contacts that are formed by disposing a first metal paste directly on a first surface of a substrate, forming a first dielectric layer over the first metal paste, disposing a second metal paste over the first dielectric layer and the first metal paste, and heating the first metal paste, the second metal paste and the first dielectric layer; and a conductive layer disposed on the first group of conductive contacts.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a block diagram of a processing sequence used to form solar cell devices in accordance with one embodiment of the present invention;

FIGS. 2A-2K depict cross-sectional views of a solar cell substrate during different stages using the processing sequence illustrated in FIG. 1 according to one embodiment of the invention;

FIG. 3 depicts a block diagram of a processing sequence used to form solar cell devices in accordance with another embodiment of the present invention;

FIGS. 4A-4C depict cross-sectional views of a solar cell substrate during different stages using the processing sequence illustrated in FIG. 3 according to another embodiment of the invention;

FIG. 5 depicts a block diagram of a processing sequence used to form solar cell devices in accordance with another embodiment of the present invention;

FIGS. 6A-6B depict cross-sectional views of a solar cell substrate during different stages using the processing sequence illustrated in FIG. 5 according to another embodiment of the invention;

FIG. 7 depicts a block diagram of a processing sequence used to form solar cell devices in accordance with another embodiment of the present invention; and

FIGS. 8A-8C depict cross-sectional views of a solar cell substrate during different stages using the processing sequence illustrated in FIG. 5 according to another embodiment of the invention.

### DETAILED DESCRIPTION

Embodiments of the present invention are directed to processes for manufacturing solar cells. Particularly, embodiments of the invention provide methods of metal contact structures onto regions of a substrate surface to directly form back-surface field (BSF) on the substrate surface without performing complicated laser ablation processes and a post ablation cleaning processes on the substrate. By doing so, a reliable and repeatable back contact metal formation process is obtained that has a low cost and reduced manufacturing complexity, without damaging the substrate or creating contamination on the substrate surface, thereby providing solar cell devices with reduced susceptibility to corrosion. The back-surface field (BSF) process provides high open circuit voltage to the device and maintains reliability due to good adhesion at the metal contact and the substrate surface. The back-surface fields (BSF) function to reduce electron-hole recombination at the back of the solar cell, thereby increasing cell efficiency. Furthermore, by co-firing (e.g., thermally processing) metal layers disposed both on a first and a second surface of a solar cell substrate, both the metal structures are formed on the first and the second surfaces of the solar cell substrate (e.g., simultaneously thermally processed), thereby eliminating manufacturing cycle time and cost to produce the solar cell devices.

One skilled in the art will appreciate that as the manufacturing cost of a solar cell substrate, which is typically the largest portion of a crystalline solar substrate manufacturing cost, decreases, due to the advancements in the process of forming the crystalline silicon ingots and the wire sawing processes used to form the substrates from the ingots, the cost of the other materials used to form a solar cell device become a larger portion of the solar cell's total manufacturing cost. Embodiments of the invention disclosed herein provide a method of forming the rear contact structure on a solar cell device that has a reduced number of processing steps that are required to form a solar cell device and, thus, a less complex solar cell processing sequence. In one example, the methods described herein can reduce more than one process step used to form a solar cell device over a conventional laser ablation and post cleaning process utilized to form metal paste layer containing solar cell device.

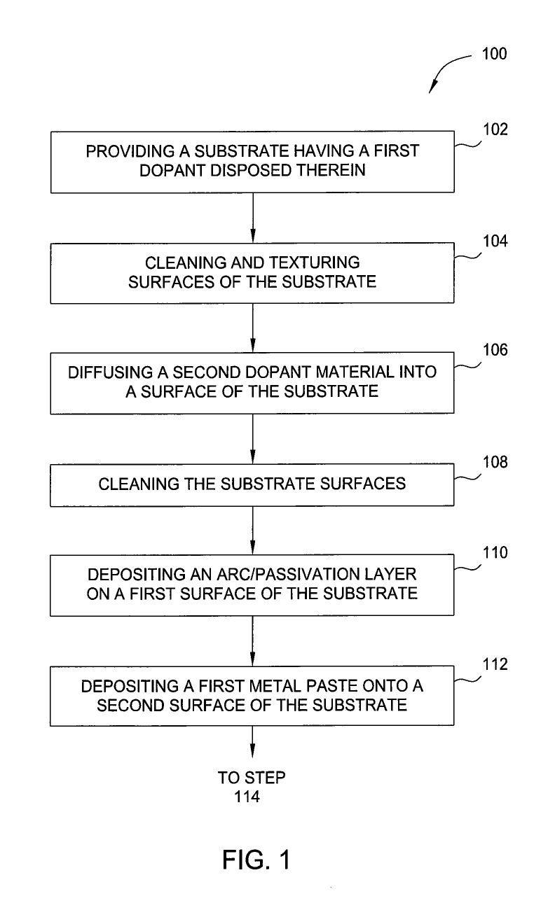

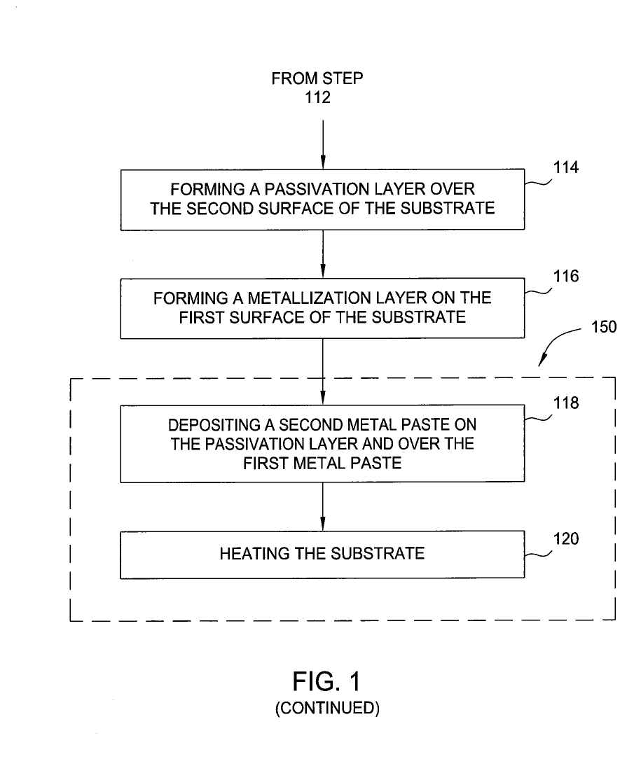

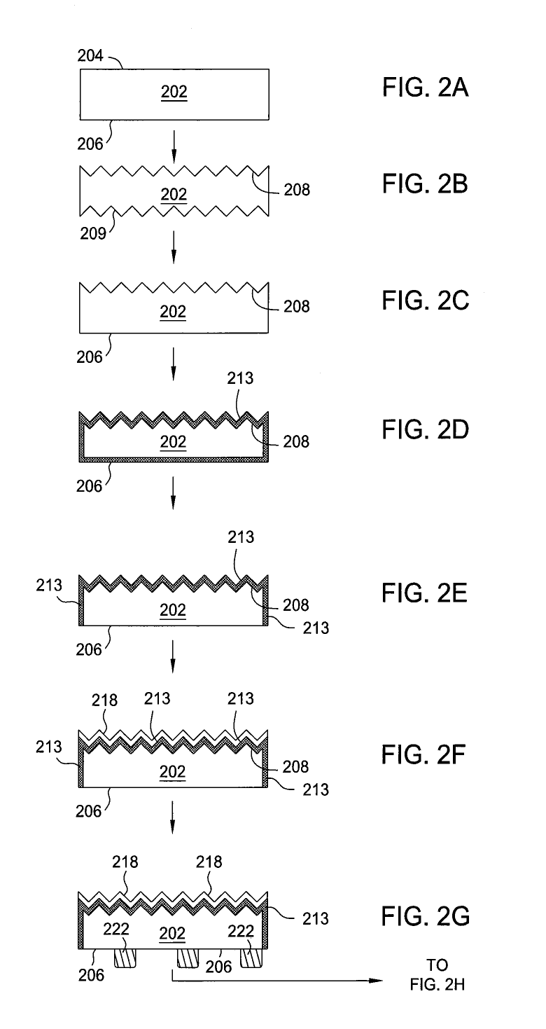

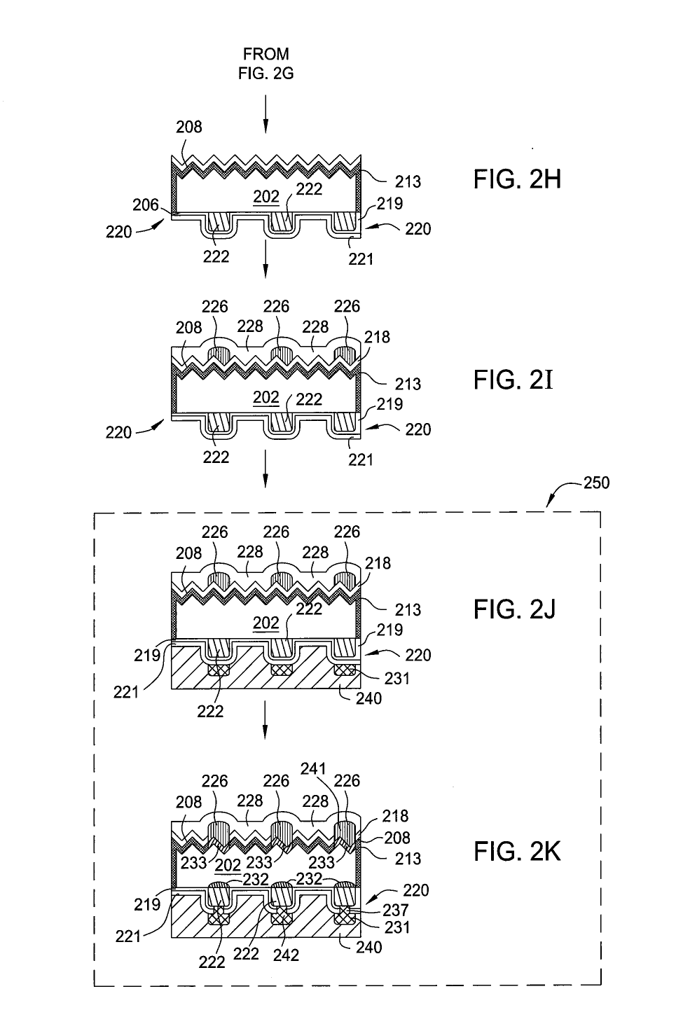

FIG. 1 depicts a block diagram of a processing sequence used to form a solar cell device in accordance with one embodiment of the present invention. FIGS. 2A-2K depict cross-sectional views of a solar cell substrate during different stages using the processing sequence illustrated in FIG. 1 according to one embodiment of the invention. It is noted that the processing sequences depicted in FIGS. 1 and 2A-2K are only used as an example of a process flow that can be used to manufacture a solar cell device. Additional steps may be added in between the steps depicted in FIG. 1 as needed to form a desirable solar cell device. Similarly, some steps depicted herein may also be eliminated as needed. It is contemplated that one or more metal or dielectric layers formed on a front or a back side of a substrate may be formed at any desired stage as needed.

In the embodiment, as depicted in FIGS. 1 and 2A, the process starts at step 102 by providing a substrate 202 having dopants disposed in one or more surfaces of the substrate 202. The substrate 202 may be a single crystal or multicrystalline silicon substrate, silicon containing substrate, doped silicon containing substrate, or other suitable substrates. In one embodiment, the substrate 202 is a doped silicon containing substrate with either p-type dopants or n-type dopants disposed therein. In one configuration, the substrate 202 is a p-type crystalline silicon (c-Si) substrate. P-type dopants used in silicon solar cell manufacturing are chemical elements, such as, boron (B), aluminum (Al) or gallium (Ga). In another configuration, the crystalline silicon substrate 202 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, for example in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Although the embodiment depicted herein and relevant discussion thereof primarily discuss the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate that is used, as will be discussed below.

At step 104, the substrate 202 is cleaned and textured. The cleaning process cleans surfaces 204, 206 of the substrate 202 to remove any undesirable materials and then the texturing process roughens the first surface 204 of the substrate 202 to form a textured surface 208, as shown in FIG. 2B. The substrate 202 has the first surface 204 (e.g., a front surface) and the second surface 206 (e.g., a back surface), which is generally opposite to the first surface 204 and on the opposite side of the substrate 202. The substrate 202 may be cleaned using a wet cleaning process in which they are sprayed with a cleaning solution. The cleaning solution may be any conventional cleaning solution, such as HF-last type cleaning solution, ozonated water cleaning solution, hydrofluoric acid (HF) and hydrogen peroxide (H₂O₂) solution, or other suitable cleaning solution. The cleaning process may be performed on the substrate 202 for between about 5 seconds and about 600 seconds, such as about 120 seconds.

The textured surface 208 on the front side of the solar cell substrate 202 is adapted to receive sunlight after the solar cell has been formed. The textured surface 208 is formed to enhance light trapping in the solar cells to improve conversion efficiency. The second surface 206 of the substrate 202 may be textured during the texturing process as well. In one example, the substrate 202 is etched in an etching solution comprising between about 2.7% by volume of potassium hydroxide (KOH) and about 4500 ppm of 300 MW PEG that is maintained at a temperature of about 79-80° C. for about 30 minutes. In one embodiment, the etching solution for etching a silicon substrate may be an aqueous potassium hydroxide (KOH), sodium hydroxide (NaOH), aqueous ammonia (NH₄OH), tetramethylammonium hydroxide (TMAH; or (CH₃)₄NOH), or other similar basic solution. The etching solution will generally anisotropically etch the substrate 202, forming pyramids on the textured surfaces 208 and 209 of the substrate 202.

In some embodiments of step 104, a rear surface polishing step may be performed to reduce or eliminate the surface texture formed on the surface 206 of the substrate 202 so that a relatively flat and stable rear surface 206 can be formed, as shown in FIG. 2C. The rear surface polishing process may be performed using a chemical mechanical polishing (CMP) process or other similar method that can remove the surface roughness created during the texturing process. In some embodiments of the invention, the rear surface polishing process is completed after performing one or more of the following process steps, such as after performing step 106.

At step 106, as shown in FIG. 2D, a dopant material, such as a doping gas, is used to form a doped region 213 (e.g., p⁺ or n⁺ doped region) on the surface of the solar cell substrate. In one embodiment, the doped region 213 is formed in the substrate 202 by use of a gas phase doping process. In one embodiment, the doped region 213 is between about 50 Å and about 20 μm thick and comprises an n-type or p-type dopant atom. In one embodiment, the doped region 213 may be an n-type dopant that is disposed in a p-type substrate 202.

In one embodiment, at step 106, dopants in a doping gas are diffused into the substrate 202 to form the doped region 213. In one example, phosphorus dopant atoms from the doping gas are doped into the surface of the substrate 202 by use of a phosphorous oxychloride (POCl₃) diffusion process that is performed at a relatively high processing temperature. In one example, the substrate 202 is heated to a temperature greater than about 800° C. in the presence of a dopant containing gas to cause the doping elements in the dopant containing gas to diffuse into the surfaces of the substrate to form a doped region. In one embodiment, the substrate is heated to a temperature between about 800° C. and about 1300° C. in the presence of phosphorus oxychloride (POCl₃) containing gas for between about 1 and about 120 minutes. Other examples of dopant materials may include, but are not limited to polyphosphoric acid, phosphosilicate glass precursors, phosphoric acid (H₃PO₄), phosphorus acid (H₃PO₃), hypophosphorous acid (H₃PO₂), and/or various ammonium salts thereof. In embodiments where the substrate 202 is an n-type substrate, the doped region 213 may be a p-type dopant material, such as boric acid (H₃BO₃). The processes performed during step 106 may be performed by any suitable heat treatment module. In one embodiment, the heat treatment module is a rapid thermal annealing (RTA) chamber, annealing chamber, a tube furnace or belt furnace chamber.

In an alternate embodiment of step 106, the doped region 213 may be formed by depositing or printing a dopant material in a desired pattern on the surface of the substrate 202 by the use of screen printing, ink jet printing, spray deposition, rubber stamping, laser diffusion or other similar process and then the driving the dopant atoms in the dopant material into the surface of the substrate. The doped region 213 may initially be a liquid, paste, or gel that is used to form heavily doped regions in the substrate 202. The substrate 202 is then heated to a temperature greater than about 800° C. to cause the dopants to drive-in or diffuse into the surface of the substrate 202 to form the doped region 213 shown in FIG. 2D. In one embodiment, the drive-in process is performed by heating the substrate 202 to a temperature between about 800° C. and about 1300° C. for a desired period of time, for example, about 1 minute to 120 minutes. The drive-in process may be performed by any suitable heat treatment module.

After the forming the doped region 213, the substrate 202 may be gradually cooled to a desired temperature. The temperature of the substrate 202 may be ramped down at ramp-down rate between about 5° C./sec. and about 350° C./sec. from the diffusion temperature of about 850° C. to a desired temperature of about 700° C. or less, such as about room temperature.

At step 108, a cleaning process may be optionally performed on the substrate 202 to remove any undesirable residues or oxides, such as phosphosilicate glass (PSG) layers, formed during step 106 or other previous processing steps, from the substrate 202. The clean process may be performed in a similar fashion discussed above with respect to step 104. The clean process may be performed on the substrate 202 between about 5 seconds and about 600 seconds, such as about 30 seconds to about 240 seconds.

It is noted that the doped region 213 formed on the rear surface 206 of the substrate 202 may be polished away as needed for different process requirements, as shown in FIG. 2E. The rear surface 206 may be optionally etched to remove the portion of the doped region 213 disposed thereon. The etching process may be performed in a similar fashion discussed above with respect to step 104, and may comprise applying a wet chemistry to the rear surface to selectively remove the doped region 213.

At step 110, an antireflection layer or passivation layer 218 is formed on the front textured surface 208 of the substrate 202, as shown in FIG. 2F. The antireflection layer/passivation layer 218 may optionally include a transparent conductive oxide (TCO) layer (not shown) as needed. In one example, the antireflection layer/passivation layer 218 may be a thin antireflection/passivation layer, such as silicon oxide or silicon nitride. In one embodiment, the passivation/ARC layer 218 may be a film stack may comprise a first layer that is in contact with the front textured surface 208 and a second layer that is disposed on the first layer. In one example, the first layer may comprise a silicon nitride (SiN) layer formed by a plasma enhanced chemical vapor deposition (PECVD) process that is between about 50 Angstroms (Å) and about 350 Å thick, such as 150 Å thick, and has a desirable quantity (Q₁) of trapped charge formed therein, to effectively passivate the substrate surface. In one example, the second layer may comprise a silicon nitride (SiN) layer formed by a PECVD process that is between about 400 Å and about 700 Å thick, such as 600 Å thick, which may have a desirable quantity (Q₂) of trapped charge formed therein, to effectively help bulk passivate the substrate surface. One will note that the type of charge, such as a positive or negative net charge based on the sum of Q₁ and Q₂, may be set by the type of substrate over which the passivation layers are formed. However, in one example, a total net positive charge of between about 5×10¹¹ Coulombs/cm² to about 1×10¹³ Coulombs/cm² is desirably achieved over an n-type substrate surface, whereas a total net negative charge of between about 5×10¹¹ Coulombs/cm² to about 1×10¹³ Coulombs/cm² would desirably be achieved over a p-type substrate surface. Alternately, in certain embodiments where a heterojunction type solar cell is desired, the antireflection/passivation layer 218 may include a thin (20-100 Å) intrinsic amorphous silicon (1-a-Si:H) layer followed by an ARC layer (e.g., silicon nitride), which can be deposited using a physical vapor deposition (PVD) process or a chemical vapor deposition (CVD) process.

At step 112, a first metal paste 222 is selectively deposited on the back surface 206 to form back metal contacts by use of an ink jet printing, rubber stamping, stencil printing, screen printing, or other similar process to form and define a desired pattern where electrical contacts to the underlying substrate surface (e.g., silicon) are formed, as depicted in FIG. 2G. In one embodiment, the first metal paste 222 is disposed in a desirable pattern on the substrate 102 by a screen printing process in which the back contact metal paste 222 is printed on the substrate 202 through a stainless steel screen. In one example, the screen printing process may be performed in a SoftLine™ system available from Applied Materials Italia S.r.I., which is a division of Applied Materials Inc. of Santa Clara, Calif. It is also contemplated that deposition equipment from other manufactures may also be utilized.

The first metal paste 222 may include polymer resin having metal particles disposed therein. The polymer and particle mixture is commonly known as “pastes” or “inks”. The polymer resins act as a carrier to help enable printing of the first metal paste 222 onto the second surface 206 of the substrate 202. Other organic chemicals are added to tune the viscosity, surface wetting, or other properties of the paste. The polymer resin and other organics are removed from the substrate 202 during the subsequent firing process, which will be discussed further detail below. Optionally, glass frit materials may also be included in the first metal paste 222. Chemical compounds contained in the glass frits found in the first metal paste 222 will react with the substrate 202 to allow the metallic elements, and other components of the paste, to diffuse (e.g., firing through) into the substrate 202 and form a contact with the substrate surface, as well as facilitating coalescence of the metal particles in the paste to form a conductive path through the back surface 206 to the substrate 202. Glass frits thus enable the first metal paste 222 to be formed on the substrate 202, thus allowing the metal particles to form electrical contacts to the substrate 202. In one embodiment, metal particles found in the first metal paste 222 may be selected from silver, silver alloy, copper (Cu), tin (Sn), cobalt (Co), rhenium (Rh), nickel (Ni), zinc (Zn), lead (Pb), and/or aluminum (Al), or other suitable metals to provide a proper conductive source for forming electrical contacts to the substrate surface. Additional components in the metal paste are generally selected so as to promote effective “wetting” of the substrate 202 while minimizing the amount of spreading that can affect the formed feature/contact metal patterns in the back surface 206 of the substrate 202.

In one embodiment, the first metal paste 222 includes aluminum (Al) particles disposed in a polymer resin that is used to form electrical contacts and back-surface-field (BSF) regions on the rear surface of a p-type substrate. The BSF regions formed at the contact points in a solar cell substrate are believed to be important, since they create an electric field within the substrate that “reflects” the minority carriers away from the contact regions, which can increase the likelihood of the current being collected and effectively reduce the back surface recombination velocity, hence improving a solar cell's short-circuit current and decreasing its dark saturation current. In some configurations, the aluminum paste may also include aluminum particles and a glass frit disposed therein to form aluminum metal on to the substrate surface. In one embodiment, the aluminum paste is selected to facilitate the low temperature dissolution of aluminum oxide, found in the substrate surface, and the formation of aluminum silicon alloys during a subsequent metal contact co-firing process, which will be discussed below in detail. In some configurations, the aluminum paste includes aluminum and bismuth silicides, bismuth germinate, sodium hexafluoroaluminate or other chlorine or fluorine containing compounds that bond with aluminum to form a chemically active material that can fire-through the substrate 202 and form an aluminum silicon alloy with regions of the p-type substrate 202, such as a highly aluminum-doped silicon layer, and aluminum silicon alloy, during a subsequent metal contact co-firing process. In one example, the formed pattern of metal paste features disposed on the substrate 202 include an aluminum paste that is directly disposed over on the rear surface 206 of the p-type substrate 202, wherein the patterned metal paste comprises an array of metal paste dots that are between about 20 μm and about 200 μm in size and between about 5 and 30 μm thick that are placed on between about 200 μm and 1500 μm centers over an aluminum oxide passivation layer that is between about 10 and 100 nm thick. The metal paste features may be formed in a hexagonal close packed (HCP) array, rectangular array or other desirable pattern.

At step 114, a back side passivation layer 220 is deposited on the second surface 206 (e.g., back surface) of the substrate 202, as shown in FIG. 2H. The passivation layer 220 may be a dielectric layer providing good surface/interface properties that reduce the recombination of the electrons and holes, drives and/or diffuses electrons and charge carriers. In one embodiment, the passivation layer 220 may be fabricated from a dielectric material selected from a group consisting of silicon nitride (S_{i3N4}), silicon nitride hydride (S_{ixNy}:H), silicon oxide, silicon oxynitride, a composite film of silicon oxide and silicon nitride, an aluminum oxide layer, a tantalum oxide layer, a titanium oxide layer, or any other suitable materials. In one embodiment, as illustrated in FIG. 2H, the passivation layer 220 comprises two layers or regions, such as an aluminum oxide layer (A_{ixOy}) 219 disposed on the back surface 206 of the substrate 202 and a silicon nitride layer 221 disposed on the aluminum oxide layer (A_{ixOy}) 219. The aluminum oxide layer (A_{ixOy}) may be formed by any suitable deposition techniques, such as atomic layer deposition (ALD) process, plasma enhanced chemical vapor deposition (PECVD) process, metal-organic chemical vapor deposition (MOCVD), sputter (PVD) process or the like. In an exemplary embodiment, the aluminum oxide layer (A_{ixOy}) 219 is formed by a MOCVD or ALD process having a thickness between about 5 nm and about 120 nm and the silicon nitride layer 221 is disposed on the aluminum oxide layer 219 having a thickness between about 5 nm and about 120 nm.

At step 116, metallization layers, including front contact structures 226 and/or a conductive bus-line 228, are formed on the antireflection/passivation layer 218 on the front surface of the substrate 202, as shown in FIG. 2I. The front contact structures 226 may be deposited in a desirable pattern on the surface of the antireflection/passivation layer 218 after the back contact metal paste 222 is disposed on the back surface 206 of the substrate 202. In some embodiments, vias may be formed through the antireflection/passivation layer 218 by use of an etching or laser ablation process so that portions of the front contact structures 226 and/or the conductive bus-line 228 that are disposed thereover can form good electrical contacts with the exposed potions of the doped region 213 formed on the front surface 204 of the substrate 202. In general, the front contact structures 226 may be between about 500 angstroms and about 100,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the front conductive contact 226 is a metallic paste that contains silver (Ag) and is deposited in a desired pattern by a screen printing process. The screen printing process may be performed by a Softline™ system available from Applied Materials Italia S.r.I., a division of Applied Materials, Inc. of Santa Clara, Calif.

In general, the conductive bus-line 228 is formed and attached to at least a portion of the front contact structures 226 to allow the solar cell device to be connected to other solar cells or external devices. In one embodiment, the conductive bus-line 228 is connected to the front contact structures 226 using a soldering material that may contain a solder material (e.g., Sn/Pb, Sn/Ag) if necessary. In one embodiment, the conductive bus-line 228 is about 200 microns thick and contains a metal, such as aluminum (Al), copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, each of the conductive bus-line 228 are formed from a wire that is about 30 gauge (AWG: ˜0.254 mm) or smaller in size. In one embodiment, the conductive bus-line 228 is coated with a solder material, such as a Sn/Pb or Sn/Ag solder material.

At step 118, a second metal paste 231 and a conductive layer 240 may be formed on the passivation layer 220 on the back surface 206 of the substrate 202, as shown in FIG. 2J. The second metal paste 231 may be formed, disposed, and/or deposited over the underlying first metal paste 222 so that conductive paths that extend from the back surface 206 of the substrate 202 to a portion of the second metal paste 231 during a subsequent thermal processing step, which is discussed below.

In one embodiment, the second metal paste 231 may be formed from similar materials and similar process described above with the process described to form the first metal paste 222 at step 112. In one embodiment, the second metal paste 231 is selectively deposited on top of and aligning with the first metal paste 222 by use of an ink jet printing, rubber stamping, stencil printing, screen printing, or other similar process to form and define a desired pattern. In one embodiment, the second metal paste 231 is disposed in a desirable pattern on the passivation layer 220 aligning with the first metal paste 222 by a screen printing process. In one example, the screen printing process may be performed in a SoftLine™ system available from Applied Materials Italia S.r.I., which is a division of Applied Materials Inc. of Santa Clara, Calif. It is also contemplated that deposition equipment from other manufactures may also be utilized. Examples of methods of aligning and depositing printed metal layers one on top of the other is further described in the commonly assigned U.S. patent application Ser. No. 13/202,960, filed Aug. 23, 2011, which is incorporated by reference herein.

Similar to the description above regarding the chemical composition of the first metal paste 222, the second metal paste 231 may include polymer resin having metal particles disposed therein, as discussed above. Chemical compounds contained in the second metal paste 231 assist the metallic elements, and other components of the paste, to diffuse (e.g., firing through) through the passivation layer 220 to connect with the first metal paste 222 so as to form the desired conductive paths into the substrate 202 and form a contact with the substrate surface. In one embodiment, metal particles found in the second metal paste 231 may be selected from silver, silver alloy, copper (Cu), tin (Sn), cobalt (Co), rhenium (Rh), nickel (Ni), zinc (Zn), lead (Pb), and/or aluminum (Al), or other suitable metals to provide a proper conductive source for forming electrical contacts to the substrate surface. In one embodiment, the second metal paste 231 includes aluminum (Al) particles disposed in a polymer resin that is used to form electrical contacts on the rear surface of a p-type substrate.

Subsequently, the conductive layer 240 is formed over the second metal paste 231 on the back side 206 of the substrate 202. The conductive layer 240 can be used to form a rear surface reflector that causes portions of the light passing through the substrate 202 in a formed solar cell device to be reflected back into the substrate 202 to improve solar cell efficiency. The conductive layer 240 may be a flood metal paste layer or a conventional blanket deposited metal layer or other suitable metallic materials manufactured by any suitable deposition techniques, such as screen print process, atomic layer deposition (ALD) process, physical vapor deposition (PVD) process, plasma enhanced chemical vapor deposition (PECVD) process, metal-organic chemical vapor deposition (MOCVD), sputter process or the like. The conductive layer 240 may have a thickness between about 500 angstroms and about 100,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive layer 240 comprises a flood metal paste layer. The flood metal paste layer 240 is a metallic paste that contains aluminum (Al) and is deposited by screen printing a metallic paste and heating the metallic paste to a desired temperature to sinter the paste. The screen printing process may be performed by a Softline™ system available from Applied Materials Italia S.r.I., a division of Applied materials, Inc. of Santa Clara, Calif.

At step 120, after the first and the second metal pastes 222, 231, the conductive layer 240 the front contact structures 226, and the conductive bus-line 228, which are disposed on the back surface 206 or front surface 208 as discussed above, are formed, a thermal processing step (e.g., a co-firing process or called a “co-fire-through” metallization process) is performed to simultaneously cause the first and the second metal paste 222, 231, the conductive layer 240, the front contact structures 226, and the conductive bus-line 228, all at once to densify and form good electrical contacts with the various regions of the solar cell substrate 202. The thermal processing step, or co-firing step, will also cause at least a portion of the first metal contact metal paste 222 to form reliable and high quality back-surface-field (BSF) regions 232 in the underlying substrate 202, as shown in FIG. 2K. In some configurations, during step 120, potions of the passivation layer 220 are etched through during the co-firing process, by the first and/or the second metal pastes 222, 231 to simultaneously form the BSF regions 232 and back side electrical contact regions 237, which comprise the materials found in first and the second metal pastes 222, 231 and extend from the substrate surface 206 and through the passivation layer 220. Similarly, potions of the front antireflection/passivation layer 218 are also etched through during the co-firing process, by the front contact structures 226, to form the front side electrical contact regions 233 that extend through the passivation layer stack 218. In one embodiment, the co-firing process comprises heating the substrates 202 to a peak firing temperature of between about 600 degrees Celsius and about 900 degrees Celsius, such as about 850 degrees Celsius for short time period, such as between about 5 seconds and about 15 seconds, for example, about 10 seconds. The firing process will also assist in evaporating the polymer or etchant materials found in any of the deposited metal paste layers.

After performing step 120, the regions of the patterned first and the second metal paste 222, 231 and the conductive layer 240 generally form a plurality of conductive paths 242 that each comprise at least portions of the densified first and second metal pastes 222, 231, conductive layer 240 and formed back side electrical contact regions 237. Each of the formed plurality of conductive paths 242 are in electrical contact with a BSF region 232, and extend through the passivation layer 220 to form the backside solar cell conductive contacts. If the formed conductive layer 240 is only formed over isolated regions of the substrate 202 one can then connect these regions together by depositing (e.g., screen printing and firing, MBE, PVD, CVD) another metal layer there-over to form a more complete solar cell back surface contact structure. Similarly, after performing step 120, the regions of the front contact structures 226 and the conductive bus-line 228 will densify and form a conductive path 241 that is in electrical contact with the front surface contact regions 233 and extend through the passivation layer 218 to form a front side contact structure.

It is generally desirable for step 120, and other similar processing steps discussed below (e.g., steps 306, 504, 706), to be performed using a thermal process that is similar to a conventional front contact “firing” process to assure that the conventional front side metallization processes will not be affected by the addition of the back side contact formation during this “co-firing” step. To assure that the patterned first and the second contact metal pastes 222, 231 will “fire-through” the passivation layer 220 during step 120, the thickness of the passivation layer 220, the passivation layer composition, the composition of the metal paste material(s) and the mass of each of the patterned back contact metal paste “dots” may need to be adjusted to assure that a repeatable solar cell device formation process is achieved.

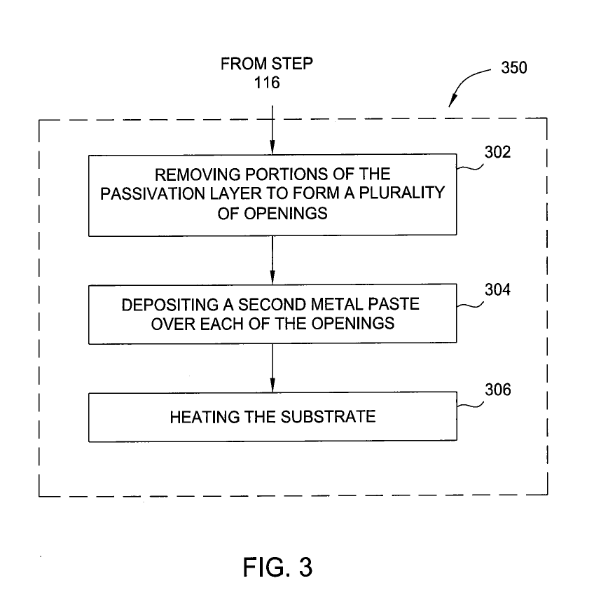

It is noted that steps 118 to 120, which are highlighted in the dotted line box 150, and the embodiments of the devices structures illustrated in FIGS. 2J to 2K, as highlighted by the dotted line box 250, may be replaced to with a different set of process steps to possibly enhance portions of the solar cell manufacturing process and/or form different solar cell structures. Some further examples of other solar cell formation processes are further discussed below with referenced to FIGS. 3-8C.

By performing the first metal paste deposition process (step 112) prior to the passivation layer deposition process (step 114), reliable BSF regions 232 can be formed and the need for conventional rear surface passivation layer patterning processes (typically including a laser ablation process and a post cleaning process) can be eliminated, since the first contact metal paste 222 is in direct contact with the solar cell substrate surface and the passivation layer may be later opened due to the use of components contained in the metal paste that allow it to fire-through the passivation layer during the co-firing process. The etchants contained in either, or both, of the first and the second metal paste layer 222, 231 can assist opening/patterning the passivation layer during the subsequently performed co-firing process, thereby forming the desired metal interconnection contact structures to complete the conductive path formation process on the rear side of the substrate. By doing so, the conventional passivation patterning process, aligning process prior to passivation patterning and cleaning process may be eliminated as needed so as to reduce the manufacture complexity and cost.

### First Alternate Processing Sequence

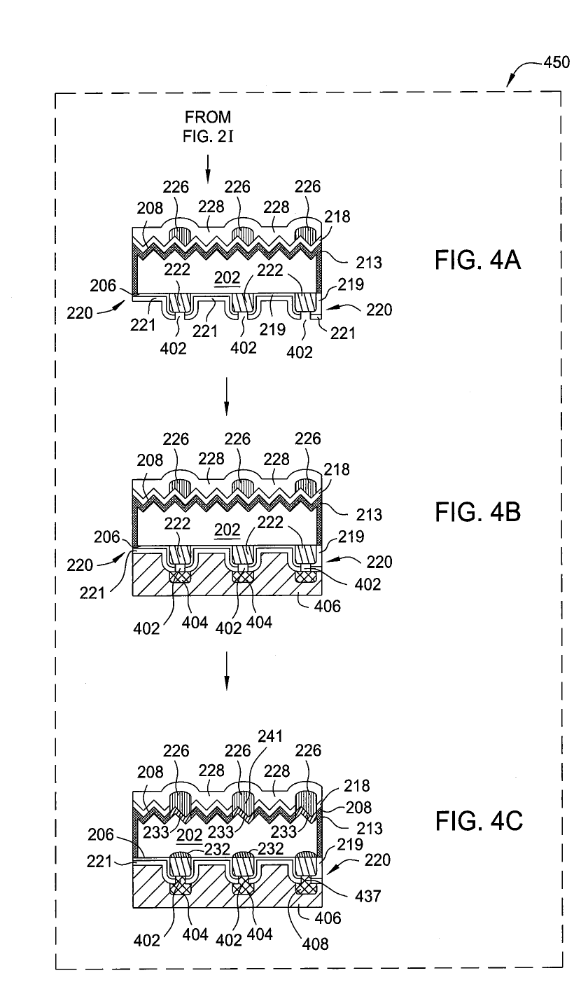

FIG. 3 depicts a block diagram of a processing sequence used to form solar cell devices in accordance with another embodiment of the present invention. FIGS. 4A-4C depict cross-sectional views of a solar cell substrate during different stages using a processing sequence that is illustrated in FIG. 3 according to another embodiment of the invention. The process steps depicted in FIG. 3, from step 302 to step 306, are performed after steps 102 to 116 (FIG. 1) have been performed, and replace steps 118-120, which are illustrated in the box 150, with these new steps 302-306 are shown in the box 350. The structures depicted in FIGS. 4A-4C are manufactured after the structure illustrated in FIG. 2I (step 116) has been formed, and thus the structures illustrated in FIGS. 2J-2K, and shown in the box 250, are replaced with the structures depicted in FIGS. 4A-4C found in box 450. FIGS. 4A-4C are cross sectional views of a solar cell device during the different processing steps performed within the processing sequence found in box 350.

At step 302, after the passivation layer 220 is formed on the back surface 206 of the substrate 202, a laser patterning process is performed to form through-holes (e.g., openings) 402 through at least a portion of the passivation layer 220 to expose the underlying first metal paste 222, as shown in FIG. 4A. In the exemplary embodiment depicted in FIG. 4A, the first layer 402 of the passivation layer 220 is an aluminum oxide layer (AlₓO_{y}) is formed by an ALD process having a thickness between about 5 nm and about 120 nm and the second layer 404 of the passivation layer 220 is a silicon nitride layer formed by a plasma enhanced chemical vapor deposition (PECVD) process having a thickness between about 5 nm and about 120 nm.

The laser patterning process forms the openings 402 in the passivation layer 220, exposing the underlying first metal paste 222, to allow portions of the later deposited second metal paste 404 or a conductive layer 406 to be disposed within the opening 402 and on the first metal paste 222. In one embodiment, the laser patterning process is performed by delivering one or more laser pulses to portions of the passivation layer 220 to form a desired pattern of openings 402 there through. The laser may have a wavelength between about 180 nm and about 1064 nm, such as about 355 nm. Each pulse is focused or imaged to spots at certain regions of the passivation layer 220 to form openings 402 therein to at least pattern portions of the passivation layer 220 to expose the underlying first metal paste 222 disposed on the substrate 202. Each opening 402 of the passivation layer 220 may be spaced at an equal distance to each other or other desired pattern. Alternatively, each opening 402 may be configured to have different distances to one and another or may be configured in any manner as needed.

In one embodiment, the spot size of the laser pulse is controlled at between about 5 μm and about 100 μm, such as about 25 μm. The spot size of the laser pulse may be configured in a manner to form spots in the passivation layer 220 with desired dimension and geometries. In one embodiment, a spot size of a laser pulse may be about 25 μm in diameter to form an opening 402 in the passivation layer 220 with a diameter about 30 μm.

The laser pulse may have energy density (e.g., fluence) between about 15 microJoules per square centimeter (mJ/cm²) and about 50 microJoules per square centimeter (mJ/cm²), such as about 30 microJoules per square centimeter (mJ/cm²) at a frequency between about 30 kHz and about 70 kHz. Each laser pulse length is configured to be about 80 nanoseconds in length. The laser pulse is continuously pulsed until the openings 402 are formed in the passivation layer 220 exposing the underlying first metal paste 222 disposed on the substrate 202. In one embodiment, the laser may be continuously pulsed for between about 500 picoseconds and about 80 nanoseconds, such as about 50 nanoseconds. After a first opening, for example, is formed in a first position defined in the passivation layer 220, a second opening is then be consecutively formed by moving the laser pulse to direct to a second location where the second opening desired to be formed in the passivation layer 220 to continue performing the laser patterning process until a desired number of the openings 402 are formed in the passivation layer 220. During the laser patterning process, the substrate 202 may be heated by the laser energy provided to the substrate 202. In one embodiment, during the laser pattering process, the substrate 202 may locally reach a temperature between about 450 degrees Celsius and about 1000 degrees Celsius.

At step 304, a second metal paste 404, similar to the second metal paste 231 depicted in FIG. 2J and described in conjunction with step 118, is formed and disposed on the openings 402 formed in the passivation layer 220 aligning with the underlying first metal paste 222, as shown in FIG. 4B. The openings 402 formed in the passivation layer 220 may help the metal elements from the second metal paste 231 to connect with the first metal paste 211 during the subsequent co-firing process. The second metal paste 231 is then connected with the underlying first metal paste 222 passing through the passivation layer 220 after the co-firing process, which will be later performed at step 306, so as to form conductive paths from the first contact metal paste 222 to the second metal paste 404.

In one embodiment, the second metal paste 231 may be formed from similar materials and deposited using a similar process as described above in conjunction with the first metal paste 222 at step 112. In one embodiment, the second metal paste 404 is selectively deposited on top of and is aligned with the first metal paste 222 by use of an ink jet printing, rubber stamping, stencil printing, screen printing, or other similar process to form and define a desired pattern. In one embodiment, the second metal paste 404 is disposed in a desired pattern over the openings 402 and on a portion of the passivation layer 220 by use of a screen printing process. In one example, the screen printing process may be performed in a SoftLine™ system available from Applied Materials Italia S.r.I., which is a division of Applied Materials Inc. of Santa Clara, Calif. It is also contemplated that deposition equipment from other manufactures may also be utilized.

Subsequently, a conductive layer 406 is formed over the second metal paste 404 on the back side 206 of the substrate 202. In the embodiment wherein the second metal paste 231 is not utilized, the conductive layer 406 may be disposed over the passivation layer 220 directly. In this particular embodiment, the openings 402 formed by the laser patterning process described at step 302 may be eliminated since the later deposited conductive layer 406 may contain etchants to etch through the passivation layer 220. The conductive layer 406, which may be similar to the conductive layer 240, may comprise a flood metal paste layer or a conventional blanket deposited metal layer or other suitable metallic materials manufactured by any suitable deposition techniques, such as screen print process, atomic layer deposition (ALD) process, physical vapor deposition (PVD) process, plasma enhanced chemical vapor deposition (PECVD) process, metal-organic chemical vapor deposition (MOCVD) process or the like. The conductive layer 406 may have a thickness between about 500 angstroms and about 100,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive layer 406 comprises a flood metal paste layer. The flood metal paste layer 406 is an inexpensive metallic paste that contains aluminum (Al) and is deposited by screen printing a metallic paste and heating the metallic paste to a desired temperature to sinter the paste. The screen printing process may be performed by a Softline™ system available from Applied Materials Italia S.r.I., a division of Applied materials, Inc. of Santa Clara, Calif.

At step 306, similar to the processes performed at step 120 depicted in FIG. 1 and FIG. 2K, after the first and the second metal pastes 222, 404, the conductive layer 406, the front contact structures 226 and the conductive bus-line 228 are all formed, a co-firing process (e.g., thermal processing step) may be performed to simultaneously thermally process these layers, as shown in FIG. 4C. In some configurations, during step 120, any potions of the remaining passivation layer 220 in the openings 402 are etched through during the co-firing process, by the first and/or the second metal pastes 222, 404, to simultaneously form the BSF regions 232 and back side electrical contact regions 437, which comprise the materials found in first and the second metal pastes 222, 404 and extend from the substrate surface 206 and through the passivation layer 220. During step 306, the second metal paste 404 (and/or portion of the first metal paste 222) and the first metal paste 222 diffuse together to form an electrical connection within the openings 402 formed in the passivation layer 220. Accordingly, the openings 402 is then filled with the metal elements diffused either from the second metal paste 404, from the conductive layer 406 or from the first metal paste 222, forming the desired back contact regions 437. In one embodiment, the co-firing process comprises heating the substrates 202 to a peak firing temperature of between about 600 degrees Celsius and about 900 degrees Celsius, such as about 850 degrees Celsius for short time period, such as between about 5 seconds and about 15 seconds, for example, about 10 seconds. The firing process will also assist in evaporating the polymer or etchant materials found in any of the metal paste materials.

After performing step 306, the regions of the patterned first and the second metal paste 222, 404 and the conductive layer 406 generally form a plurality of conductive paths 408 that each comprise at least portions of the densified first and second metal pastes 222, 404, conductive layer 406 and formed back side electrical contact regions 437. Each of the formed plurality of conductive paths 408 are in electrical contact with a BSF region 232, and extend through the passivation layer 220 to form the backside solar cell conductive contacts. If the formed conductive layer 406 is only formed over isolated regions of the substrate 202 one can then connect these regions together by depositing (e.g., screen printing and firing, MBE, PVD, CVD) another metal layer there-over to form a more complete solar cell back surface contact structure. Similarly, potions of the front antireflection/passivation layer 218 are also etched through during the co-firing process, by the front contact structures 226, to form the front side electrical contact regions 233 that extend through the passivation layer stack 218.

### Second Alternate Processing Sequence

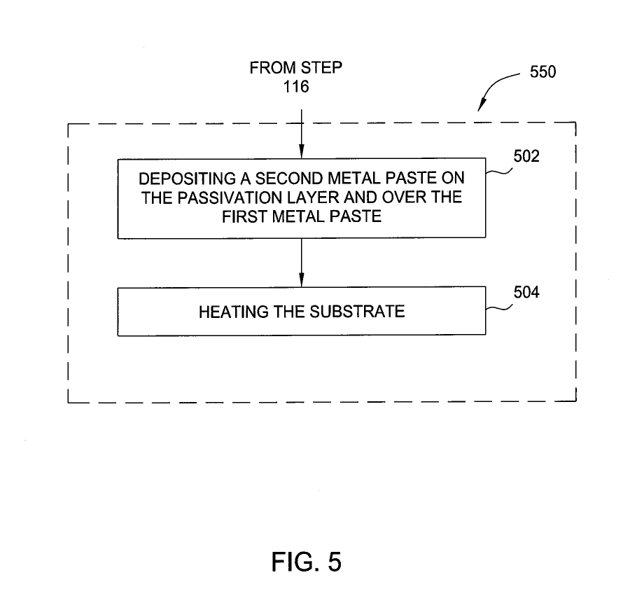

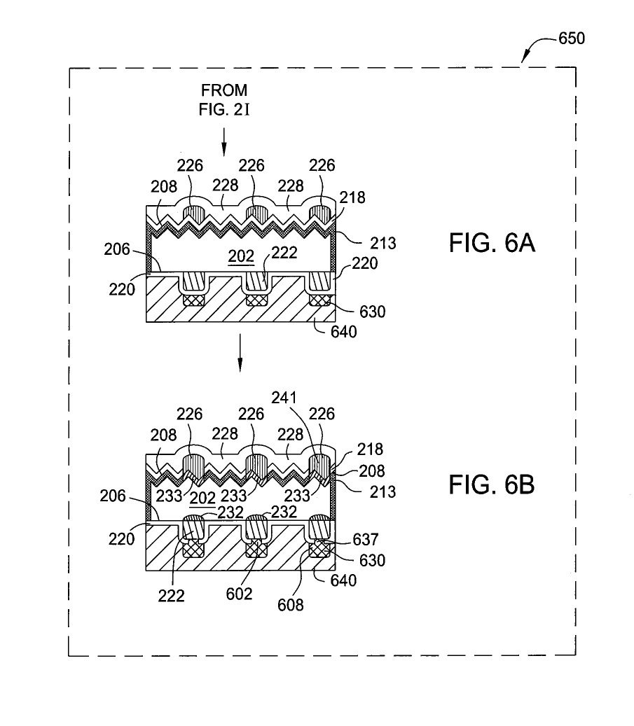

FIG. 5 depicts a block diagram of a processing sequence used to form solar cell devices in accordance with another embodiment of the present invention. FIGS. 6A-6B are cross-sectional views that illustrate regions of a solar cell substrate during different stages of a processing sequence illustrated in FIG. 5 according to another embodiment of the invention. The steps 502 to 504 shown in box 550, which are depicted in FIG. 5, are performed after steps 102-116 (FIG. 1) have been performed, and thus may replace steps 118-120 shown in the box 150. The structures depicted in FIGS. 6A-6B are manufactured after the structure illustrated in FIG. 2I (step 116) has been formed, and thus the structures illustrated in FIGS. 2J-2K, and shown in the box 250, are replaced with the structures depicted in FIGS. 6A-6B found in box 650. FIGS. 6A-6B are cross sectional views of a solar cell device during the different processing steps performed within the processing sequence found in box 550.

At step 502, similar to the process 100 depicted in FIG. 1 at step 118, after the passivation layer 220 is formed on the back surface 206 of the substrate 202, a second metal paste 630 and a conductive layer 640 may be formed on the passivation layer 220 on the back surface 206 of the substrate 202, as shown in FIG. 6A. The difference of the structure depicted in FIG. 6A as compared to the structure depicted in FIG. 2J is that the passivation layer 220 depicted in FIG. 6A is a single layer, instead of the composite film stack having the second layer 221 disposed on the first layer 219 depicted in FIG. 2J. In the embodiment depicted in FIG. 6A, the single layer passivation layer 220 may be fabricated from a dielectric material selected from a group consisting of silicon nitride (Si₃N₄), silicon nitride hydride (SiₓN_{y}:H), silicon oxide, silicon oxynitride, an aluminum oxide layer, a tantalum oxide layer, a titanium oxide layer, or any other suitable materials. In one embodiment, the passivation layer 220 utilized herein is an aluminum oxide layer (AlₓO_{y}) disposed on the back surface 206 of the substrate 202. The aluminum oxide layer (AlₓO_{y}) may be formed by any suitable deposition techniques, such as atomic layer deposition (ALD) process, plasma enhanced chemical vapor deposition (PECVD) process, metal-organic chemical vapor deposition (MOCVD), sputter process or the like. In an exemplary embodiment, the aluminum oxide layer (AlₓO_{y}) is formed by a MOCVD or ALD process having a thickness between about 5 nm and about 120 nm.

Similar to the description above with referenced to FIG. 2J at step 118, the second metal paste 630 may be formed, disposed, and/or deposited over the underlying first metal paste 222 so that conductive paths that extend from the back surface 206 of the substrate 202 to a portion of the second metal paste 231 during a subsequent thermal processing step, which is discussed below.

Subsequently, the conductive layer 640 is then formed over the second metal paste 630 on the back side 206 of the substrate 202. The conductive layer 640 can be used to form a rear surface reflector that causes portions of the light passing through the substrate 202 in a formed solar cell device to be reflected back into the substrate 202 to improve solar cell efficiency. In the embodiment depicted in FIG. 6A, the conductive layer 640 is a conventional blanket deposited metal layer or other suitable metallic materials manufactured by any suitable deposition techniques, such as screen print process, atomic layer deposition (ALD) process, physical vapor deposition (PVD) process, plasma enhanced chemical vapor deposition (PECVD) process, metal-organic chemical vapor deposition (MOCVD), sputter process or the like. The conductive layer 640 may have a thickness between about 500 angstroms and about 50,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive layer 640 is a conventional PVD deposited aluminum (Al) layer.

At step 504, after the first and the second metal pastes 222, 630, the conductive layer 640 the front contact structures 226, and the conductive bus-line 228, which are disposed on the back surface 206 or front surface 208, as discussed above, are formed, a thermal processing step (e.g., a co-firing process) is performed to simultaneously cause the first and the second metal paste 222, 630, the conductive layer 240, the front contact structures 226, and the conductive bus-line 228, all at once to densify and form good electrical contacts with the various regions of the solar cell substrate 202, as shown in FIG. 6B.

The thermal processing step, or co-firing step, will also cause at least a portion of the first metal contact metal paste 222 to form reliable and high quality back-surface-field (BSF) regions 232 in the underlying substrate 202, as shown in FIG. 6B. In some configurations, during step 504, potions of the passivation layer 220 are etched through during the co-firing process, by the first and/or the second metal pastes 222, 630 to simultaneously form the BSF regions 232 and back side electrical contact regions 637, which comprise the materials found in first and the second metal pastes 222, 630 and extend from the substrate surface 206 and through the passivation layer 220. Similarly, potions of the front antireflection/passivation layer 218 are also etched through during the co-firing process, by the front contact structures 226, to form the front side electrical contact regions 233 that extend through the passivation layer 218. The thermal processing step (the co-firing process) is similar to the thermal processing step (the co-firing process) described at step 120, 306 with referenced to FIG. 2K and FIG. 4C described above in FIGS. 1-4C. In one embodiment, the co-firing process comprises heating the substrates 202 to a peak firing temperature of between about 600 degrees Celsius and about 900 degrees Celsius, such as about 850 degrees Celsius for short time period, such as between about 5 seconds and about 15 seconds, for example, about 10 seconds. The firing process will also assist in evaporating the polymer or etchant materials found in any of the deposited metal paste layers.

After performing step 504, the regions of the patterned first and the second metal paste 222, 630 and the conductive layer 640 will densify and form a conductive path 608 that is in electrical contact with the rear surface contact region 232 and extend through the passivation layer 220 so that these formed regions of patterned metal contacts can be subsequently connected together to form a back surface contact structure. Similarly, after performing step 504, potions of the front antireflection/passivation layer 218 are also etched through during the co-firing process, by the front contact structures 226, to form the front side electrical contact regions 233 that extend through the passivation layer stack 218. In one embodiment, the co-firing process comprises heating the substrates 202 to a peak firing temperature of between about 600 degrees Celsius and about 900 degrees Celsius, such as about 850 degrees Celsius for short time period, such as between about 5 seconds and about 15 seconds, for example, about 10 seconds. The firing process will also assist in evaporating the polymer or etchant materials found in any of the deposited metal paste layers.

### Third Alternate Processing Sequence

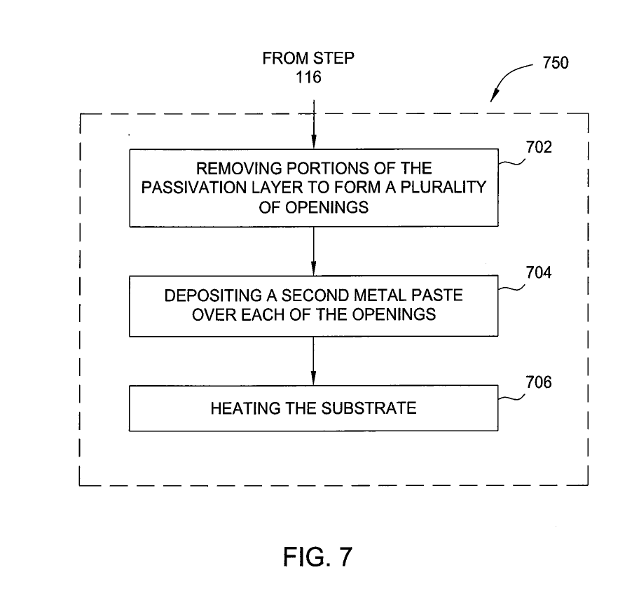

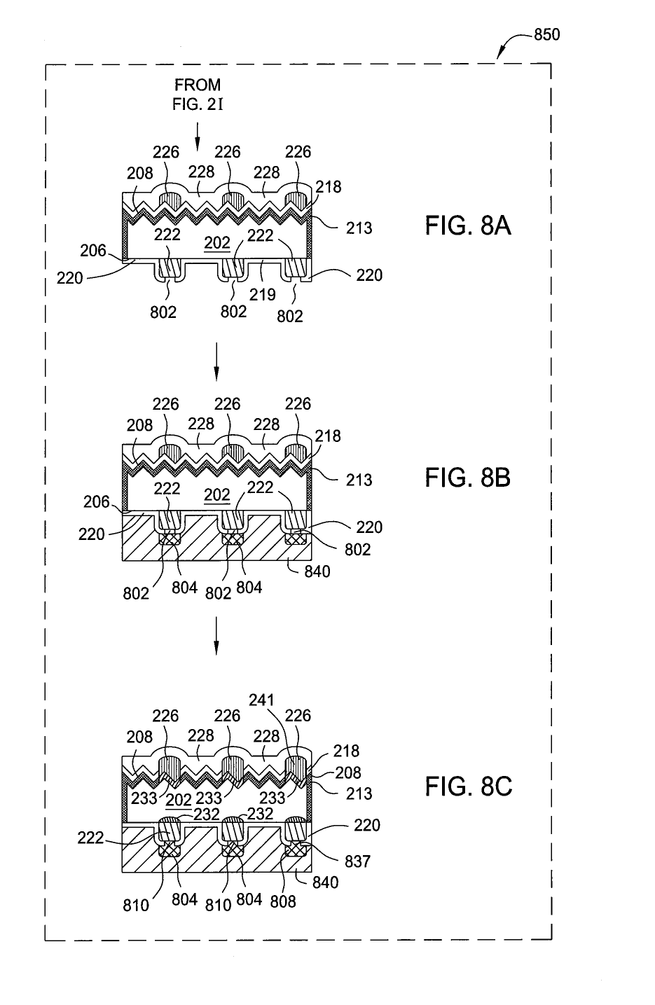

FIG. 7 depicts a block diagram of a processing sequence used to form solar cell devices in accordance with another embodiment of the present invention. FIGS. 8A-8C are cross-sectional views that illustrate portions of a solar cell substrate during different stages of a processing sequence shown in FIG. 7 according to another embodiment of the invention. The steps 702 to 706 shown in box 750, which are depicted in FIG. 7, are generally performed after steps 102-116 (FIG. 1) have been performed, and thus may replace steps 118-120 shown in the box 150. The structures depicted in FIGS. 8A-8C are manufactured after the structure illustrated in FIG. 2I (step 116) has been formed, and thus the structures illustrated in FIGS. 2J-2K, and shown in the box 250, are replaced with the structures depicted in FIGS. 8A-8C found in box 850. FIGS. 8A-8C are cross sectional views of a solar cell device during the different processing steps performed within the processing sequence found in box 750.

At step 702, similar to the description of step 302 with referenced to FIG. 4A, after the passivation layer 220 is formed on the back surface 206 of the substrate 202, a laser patterning process is performed to form through-holes (e.g., openings) 802 through at least a portion of the passivation layer 220 to expose the underlying first metal paste 222, as shown in FIG. 8A. The difference of the structure depicted in FIG. 8A as compared to the structure depicted in FIG. 4A is that the passivation layer 220 depicted in FIG. 8A is a single layer, instead of the composite film stack having the second layer 221 disposed on the first layer 219 depicted in FIG. 4A. In the embodiment depicted in FIG. 8A, the single layer passivation layer 220 may be fabricated from a dielectric material selected from a group consisting of silicon nitride (Si₃N₄), silicon nitride hydride (SiₓN_{y}:H), silicon oxide, silicon oxynitride, an aluminum oxide layer, a tantalum oxide layer, a titanium oxide layer, or any other suitable materials. In one embodiment, the passivation layer 220 utilized herein is an aluminum oxide layer (AlₓO_{y}) disposed on the back surface 206 of the substrate 202. The aluminum oxide layer (AlₓO_{y}) may be formed by any suitable deposition techniques, such as atomic layer deposition (ALD) process, plasma enhanced chemical vapor deposition (PECVD) process, metal-organic chemical vapor deposition (MOCVD), sputter process or the like. In an exemplary embodiment, the aluminum oxide layer (AlₓO_{y}) is formed by a MOCVD or ALD process having a thickness between about 5 nm and about 120 nm.

The laser patterning process forms the openings 802 in the passivation layer 220 to expose the underlying first metal paste 222 to allow portions of the later deposited second metal paste 804 and/or conductive layer 840 to be disposed thereon. In one embodiment, the laser patterning process may be similar to the laser patterning process described above at step 302 with referenced to FIG. 4A.

At step 704, a second metal paste 804, similar to the second metal paste 231 depicted in FIG. 2J and described conjunction with in step 118, is formed and disposed on the openings 802 formed in the passivation layer 220 aligning with the underlying first metal paste 222, as shown in FIG. 8B. In the embodiment wherein the second metal paste 804 is not utilized, a conductive layer 840 may be later disposed over the passivation layer 220 directly without forming the second metal paste 804. The openings 802 formed in the passivation layer 220 may help the metal elements from the second metal paste 802 to connect with the first metal paste 222 during the subsequent co-firing process. The second metal paste 804 is then connected with the underlying first metal paste 222 through the passivation layer 220 after the co-firing process, which will be later performed at step 706, so as to form conductive paths 810 from the first contact metal paste 222 to the second metal paste 804, so as to form conductive paths from the first contact metal paste 222 to the second metal paste 804.

In one embodiment, the second metal paste 804 may be formed from similar materials and similar process described above with the process described to form the first metal paste 222 at step 112. In one embodiment, the second metal paste 804 is selectively deposited on top of and aligned with the first metal paste 222 by use of an ink jet printing, rubber stamping, stencil printing, screen printing, or other similar process to form and define a desired pattern. In one embodiment, the second metal paste 804 is disposed in a desired pattern over the openings 802 and on a portion of the passivation layer 220 by use of a screen printing process. In one example, the screen printing process may be performed in a SoftLine™ system available from Applied Materials Italia S.r.I., which is a division of Applied Materials Inc. of Santa Clara, Calif. It is also contemplated that deposition equipment from other manufactures may also be utilized.

Subsequently, a conductive layer 840 is formed over the second metal paste 804 on the back side 206 of the substrate 202. In the embodiment wherein the second metal paste 804 is not utilized, the conductive layer 840 may be disposed over the passivation layer 220 directly. In the embodiment wherein the second metal paste 804 is not utilized, the conductive layer 840 may be disposed over the passivation layer 220 directly. In this particular embodiment, the openings 802 formed by the laser patterning process described at step 702 may be eliminated since the later deposited conductive layer 406 may contain etchants to etch through the passivation layer 220. In the embodiment depicted in FIG. 8B, the conductive layer 840 is a conventional blanket deposited metal layer or other suitable metallic materials manufactured by any suitable deposition techniques, such as screen print process, atomic layer deposition (ALD) process, physical vapor deposition (PVD) process, plasma enhanced chemical vapor deposition (PECVD) process, metal-organic chemical vapor deposition (MOCVD), sputter process or the like. The conductive layer 840 may have a thickness between about 500 angstroms and about 50,000 angstroms (Å) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the conductive layer 840 is a conventional PVD deposited aluminum (Al) layer.

At step 706, similar to the processes performed at step 120 depicted in FIG. 1 and FIG. 2K, after the first and/or the second metal pastes 222, 804, the conductive layer 840, the front contact structures 226 and the conductive bus-line 228 are all formed, a co-firing process (e.g., thermal processing step) may be performed to simultaneously thermally process these layers, as shown in FIG. 8C. In some configurations, during step 706, any potions of the remaining passivation layer 220 in the openings 802 are etched through during the co-firing process, by the first and/or the second metal pastes 222, 804, to simultaneously form the BSF regions 232 and back side electrical contact regions 808, which comprise the materials found in first and the second metal pastes 222, 804 and extend from the substrate surface 206 and through the passivation layer 220. During step 706, the second metal paste 804 (and/or portion of the first metal paste 222) and the first metal paste 222 diffuse together to form an electrical connection within the openings 837 formed in the passivation layer 220. Accordingly, the openings 802 is then filled with the metal elements diffused either from the second metal paste 804 or from the first metal paste 222, forming the desired back contact regions 837. In one embodiment, the co-firing process comprises heating the substrates 202 to a peak firing temperature of between about 600 degrees Celsius and about 900 degrees Celsius, such as about 800 degrees Celsius for short time period, such as between about 8 seconds and about 12 seconds, for example, about 10 seconds. The firing process will also assist in evaporating the polymer or etchant materials found in any of the metal paste materials.

After performing step 706, the regions of the patterned first and the second metal paste 222, 804 and the conductive layer 840 generally form a plurality of conductive paths 808 that each comprise at least portions of the densified first and second metal pastes 222, 804, conductive layer 840 and formed back side electrical contact regions 837. Each of the formed plurality of conductive paths 808 are in electrical contact with a BSF region 232, and extend through the passivation layer 220 to form the backside solar cell conductive contacts. If the formed conductive layer 840 is only formed over isolated regions of the substrate 202 one can then connect these regions together by depositing (e.g., screen printing and firing, MBE, PVD, CVD) another metal layer there-over to form a more complete solar cell back surface contact structure. Similarly, potions of the front antireflection/passivation layer 218 are also etched through during the co-firing process, by the front contact structures 226, to form the front side electrical contact regions 233 that extend through the passivation layer stack 218.

Therefore, by forming a metal paste deposition process directly on a back side of a substrate prior to deposition of a passivation layer thereover, the conventional passivation patterning process (typically including a laser ablation process and/or a post cleaning process) may be eliminated since the passivation layer may be later opened or patterned by etchants contained in the metal paste during the subsequently performed co-firing process. The etchants contained in metal paste layer can assist opening/patterning the passivation layer during the subsequently performed co-firing process, thereby forming the desired metal interconnection contact structures to complete the conductive path formation process on the rear side of the substrate. without the conventional passivation patterning process, aligning process prior to passivation patterning and cleaning process. In this way, some passivation removal process and/or cleaning process may be eliminated during the solar cell device manufacture process so as to reduce the manufacture complexity and cost and, thus, the conversion efficiency of the solar cell devices may be increased and the cost to produce the solar cell can be reduced.

While the foregoing is directed to embodiments of the present invention, other and further embodiments of the invention may be devised without departing from the basic scope thereof, and the scope thereof is determined by the claims that follow.

What is claimed is:

1. A method of manufacturing a solar cell device, comprising:
selectively disposing a first metal paste in a first pattern on a first surface of a substrate;
depositing a first dielectric layer over the first metal paste and the first surface of the substrate;
depositing a second metal paste in a second pattern on the first dielectric layer and over the first metal paste; and
simultaneously heating the substrate to form a first group of contacts on the first surface of the substrate, wherein each of the first group of contacts comprise at least a portion of the first and second metal pastes, and extend through the first dielectric layer.

2. The method of claim 1, wherein the substrate has a second surface that has a second dielectric layer disposed thereon;
selectively disposing a third metal paste in a third pattern on a surface of the second dielectric layer.

3. The method of claim 2, wherein simultaneously heating the substrate further comprises heating the third metal paste disposed on the second surface of the substrate while simultaneously heating the first and the second metal pastes.

4. The method of claim 1, wherein forming the first dielectric layer over the first metal paste further comprises:
performing a laser ablation process to remove a portion of the first dielectric layer from the first surface of the substrate, wherein the laser ablation process forms openings in the first dielectric layer exposing the underlying first metal paste.

5. The method of claim 4, wherein depositing a second metal paste further comprises depositing the second metal paste over the openings of the first dielectric layer.

6. The method of claim 1, wherein depositing a second metal paste further comprises:
depositing a conductive layer over the second metal paste.

7. The method of claim 6, wherein the conductive layer is a flood metal paste or a PVD deposited metal blanket layer.

8. The method of claim 6, wherein the conductive layer is an aluminum layer.

9. The method of claim 1, wherein the first, the second and the third metal paste comprises aluminum, silver or copper.

10. The method of claim 1, wherein the first dielectric layer comprises an aluminum oxide layer or a film stack including an aluminum oxide layer and a silicon nitride layer, wherein the silicon nitride layer is disposed on the aluminum oxide layer that is disposed over the first side of the substrate.

11. The method of claim 1, wherein simultaneously heating the first and the second metal pastes further comprises:
diffusing the first metal paste through the first dielectric layer to the second metal paste;
forming a metal interconnection structure on the first surface of the substrate.

12. The method of claim 2, wherein selectively disposing the third metal paste on the second dielectric layer further comprises forming a metal bus line layer on the third metal paste.

13. The method of claim 12, wherein the metal bus line layer is an aluminum layer.

14. The method of claim 1, wherein simultaneously heating the first and the second metal pastes further comprises:
diffusing the first metal paste into the first surface of the substrate; and
forming back-surface-field (BSF) regions on the first surface of the substrate.

15. A method of manufacturing a solar cell device, comprising:
selectively disposing a first metal paste in a first pattern on a first surface of a substrate;
depositing a first dielectric layer over the first metal paste on the first surface of the substrate;
depositing a second metal paste in a second pattern over the first dielectric layer align with the first metal paste;
forming a third metal paste in a third pattern on a second dielectric layer disposed on a second surface of the substrate; and
simultaneously heating the first, the second, and the third metal pastes to form a first group of contacts on the first surface of the substrate and a second group of the contacts on the second surface of the substrate, wherein at least a portion of the first and second metal pastes forms the first group of contacts that each extend through the first dielectric layer.

16. The method of claim 15, further comprising:
coupling a conductive layer to the first group of contacts formed in the first dielectric layer.

17. The method of claim 16, wherein the conductive layer is a flood metal paste or a PVD deposited metal blanket layer.

18. The method of claim 17, wherein the conductive layer is an aluminum layer.

19. The method of claim 15, wherein forming the first dielectric layer over the first metal paste further comprises:
performing a laser ablation process to remove a portion of the first dielectric layer from the first surface of the substrate, wherein the laser ablation process forms openings in the first dielectric layer exposing the underlying first metal paste.

20. The method of claim 19, wherein the second metal paste is deposited over the openings of the first dielectric layer.

21. The method of claim 15, wherein the first, the second and the third metal pastes comprises aluminum, silver or copper.

22. The method of claim 15, wherein the first dielectric layer comprises an aluminum oxide layer or a film stack including an aluminum oxide layer and a silicon nitride layer, wherein the silicon nitride layer is disposed on the aluminum oxide layer disposed on the first side of the substrate.

23. A solar cell device, comprising:
a first group of conductive contacts that are formed by:
disposing a first metal paste directly on a first surface of a substrate;
forming a first dielectric layer over the first metal paste;
disposing a second metal paste over the first dielectric layer and the first metal paste; and
heating the first metal paste, the second metal paste and the first dielectric layer; and
a conductive layer disposed on the first group of conductive contacts.

24. The solar cell device of claim 23, further comprising:
a second dielectric layer disposed on a second surface of the substrate;
a plurality of metal regions disposed over the second surface and extending through the second dielectric layer and contacting the second surface of the substrate; and
a conductive bus-line disposed over the plurality of metal regions.

25. The solar cell device of claim 23, wherein the substrate has a first type of dopants doped therein and has a second type of dopants doped on an outer surface of the substrate.
